(19) United States
(12) Patent Application Publication
(10) Pub. No.: US 2014/0175473 A1
(43) Pub. Date: Jun. 26, 2014

(54) LIGHT EMITTING DIODES INCLUDING LIGHT EMITTING SURFACE BARRIER LAYERS, AND METHODS OF FABRICATING SAME

(71) Applicant: CREE, INC., Durham, NC (US)

(72) Inventors: Matthew Donofrio, Raleigh, NC (US); Barry Rayfield, Wake Forest, NC (US); Shaow B. Lin, Cary, NC (US)

(73) Assignee: Cree, Inc., Durham, NC (US)

(21) Appl. No.: 13/758,565

(22) Filed: Feb. 4, 2013

Related U.S. Application Data
(60) Provisional application No. 61/740,659, filed on Dec. 21, 2012.

(51) Int. Cl. H01L 33/56; H01L 33/50

(52) U.S. Cl. CPC H01L 33/56; H01L 33/50
USPC 257/94; 257/100; 438/26

(57) ABSTRACT

A light emitting device includes a Light Emitting Diode (LED) having a light emitting surface, a silicon nitride layer on the light emitting surface and a sealed environment surrounding the light emitting surface. The silicon nitride layer may be directly on and cover the light emitting surface. The silicon nitride layer may completely cover the light emitting surface. The silicon nitride layer may provide a substance blocking layer such as a moisture blocking layer and/or a carbon blocking layer that can prevent moisture and/or carbon, such as Volatile Organic Compounds (VOCs) that contain carbon, from reaching the light emitting surface.

### CROSS-REFERENCE TO RELATED APPLICATION

The present application claims the benefit of Provisional Application No. 61/740,659, filed Dec. 21, 2012, entitled Light Emitting Diodes Including Light Emitting Surface Barrier Layers, and Methods of Fabricating Same, the disclosure of which is hereby incorporated herein by reference in its entirety as if set forth fully herein.

### BACKGROUND

This invention relates to light emitting devices and methods of manufacturing the same, and more particularly, to light emitting devices that include Light Emitting Diodes (LEDs) and methods of manufacturing the same.

LEDs are widely known solid-state lighting elements that are capable of generating light upon application of voltage thereto. LEDs generally include a diode region having first and second opposing faces, and include therein an n-type layer, a p-type layer and a p-n junction. An anode contact ohmically contacts the p-type layer and a cathode contact ohmically contacts the n-type layer. The diode region may be epitaxially formed on a substrate, such as a sapphire, silicon, silicon carbide, gallium arsenide, gallium nitride, etc., growth substrate, but the completed device may not include a substrate. The diode region may be fabricated, for example, from silicon carbide, gallium nitride, gallium phosphide, aluminum nitride and/or gallium arsenide-based materials and/or from organic semiconductor-based materials. Finally, the light radiated by the LED may be in the visible or ultraviolet (UV) regions, and the LED may incorporate wavelength conversion material such as phosphor.

LEDs are increasingly being used in lighting/illumination applications, with a goal being to provide a replacement for ubiquitous incandescent and fluorescent light bulbs.

Conventional incandescent and fluorescent light bulbs typically operate in a sealed environment, conventionally referred to as a “bulb” or “tube”. In contrast, LEDs generally do not operate in a sealed environment. In fact, various LED manufacturers caution against operating an LED in a sealed environment.

For example, a document entitled “Cree® XLamp® LEDs Chemical Compatibility” (Document CLD-AP63 Rev 0B, 2011) explains that the presence of incompatible Volatile Organic Compounds (VOCs) in LED illumination systems can accelerate the degradation or impair the performance of LEDs from any manufacturer. This chemical incompatibility is often a localized phenomenon, occurring in sealed portions of the systems where LEDs operate at elevated temperatures, with little or no air movement. As also noted, LEDs often include a silicone-based dome, lens or encapsulant. Moreover, glues, conformal coatings, O-rings, gaskets and potting compounds are frequently used in the construction of luminaires or other solid-state lighting products. When operating the lighting products, some of these materials emit VOCs. In a sealed environment, the VOCs will surround the LED and diffuse into the porous silicone encapsulant. Accordingly, as noted, a long list of chemicals are deemed to have incompatible chemistry with an LED, and it is recommended to not use these chemicals anywhere in an LED system.

Similar observations may be found in a document entitled “LUXEOIV® LED Assembly and Handling Information” (Philips Lumileds Application Brief AB32, Mar. 2, 2012), which notes, at Page 37, that LUXEON LEDs contain a silicone overcoat and silicone lens. This document observes that, as with most silicones used in LED optics, care must be taken to prevent any incompatible chemicals from directly or indirectly reacting with the silicone. Since the silicone overcoat is gas permeable, oxygen and VOC gas molecules can diffuse into the silicone overcoat, and produce discoloration and surface damage. Accordingly, as noted, careful consideration must be given to whether LUXEON LEDs are enclosed in an airtight environment.

Unfortunately, it is often desirable to use LEDs in a sealed environment. In one example, a sealed helium environment may be desired to increase the heat transfer from the LED. Various other sealed solid, gel and/or gaseous environments may be used for various other purposes. As such, development has focused on improving the materials that are used with the light emitting device, including silicone encapsulants, glues, gaskets, etc., to reduce the production of VOCs. Thus, attempts have been made to reduce or eliminate materials that are incompatible with an LED in a sealed environment and/or to formulate higher performance silicone encapsulants and other materials.

### SUMMARY

A light emitting device according to various embodiments described herein includes a Light Emitting Diode (LED) having a light emitting surface, a silicon nitride layer on the light emitting surface and a sealed environment surrounding the light emitting surface. In some embodiments, the silicon nitride layer is directly on and covers the light emitting surface. In some embodiments, the silicon nitride layer completely covers the light emitting surface. In some embodiments, the sealed environment comprises a sealed gaseous environment. Moreover, the sealed gaseous environment may consist essentially of helium in some embodiments, and, in other embodiments, the sealed gaseous environment comprises less oxygen than air and/or more helium than air.

The silicon nitride layer may provide an embodiment of a substance blocking or impermeable layer that can prevent substances such as moisture, carbon, and/or Volatile Organic Compounds (VOCs) that contain carbon, from reaching the light emitting surface. The substance blocking layer is directly on, and completely covers, the light emitting surface, in some embodiments. In some embodiments, the substance blocking layer may comprise a plurality of sublayers. Moreover, materials other than silicon nitride, such as boron nitride and/or other inorganic/organic materials, may also be used.

Light emitting devices according to various embodiments described herein may be used in a sealed environment. However, according to other embodiments, an LED including a silicon nitride layer or a substance blocking layer may be provided directly on and completely covering the light emitting surface thereof, even when the LED is not used in a sealed environment.

Various embodiments of LEDs may be provided according to any of the embodiments described herein. For example, in some embodiments, the LED comprises a diode region and a substrate, and the light emitting surface comprises an outer surface of the substrate that is free of an opaque region thereon, including a substrate face remote from the diode region and at least one substrate sidewall between the diode region and the substrate face. In these embodiments, the silicon nitride layer or substance blocking layer may be provided directly on and (completely) covering the substrate face and the at least one substrate sidewall. In other embodiments, the light emitting surface may further comprise at least one diode region sidewall, and the silicon nitride layer or substance blocking layer may further be provided directly on and (completely) covering the at least one diode region sidewall. In still other embodiments, the light emitting surface may further comprise a diode region face that is remote from the substrate, and the silicon nitride layer or substance blocking layer may be provided directly on and (completely) covering the diode region face.

In still other embodiments, the light emitting surface may comprise an outer surface of the diode region that is free of an opaque region thereon, including a diode region face remote from the substrate and at least one diode region sidewall between the substrate and the diode region face. In these embodiments, the silicon nitride layer or substance blocking layer may be provided directly on and (completely) covering the diode region face and the at least one diode region sidewall.

In any of the embodiments described herein, the diode region may comprise Group-III nitride-based semiconductor layers and the substrate may comprise silicon carbide, sapphire and/or silicon. Moreover, in any of the embodiments described herein, a phosphor layer may be provided on the silicon nitride or substance blocking layer, remote from the light emitting surface. The phosphor layer may comprise silicone with phosphor particles embedded therein.

A light emitting device may be fabricated according to various embodiments described herein, by providing a silicon nitride layer or a substance blocking layer on an exposed surface of a plurality of LEDs during wafer fabrication. Moreover, according to other embodiments described herein, the entire light emitting surface of an individual LED may not be exposed at a wafer level. Accordingly, light emitting devices may be fabricated according to other embodiments described herein, by providing a wafer including therein a plurality of LEDs, a respective one of which includes a light emitting surface; singulating the individual LEDs in the wafer; and forming a silicon nitride layer or a substance blocking layer on the light emitting surfaces of the individual LEDs that were singulated. According to some embodiments, a stretchable film may be provided on a face of a wafer that includes therein a plurality of LEDs. The stretchable film is then stretched to expose the light emitting surfaces on the sides of the individual LEDs. A silicon nitride layer is then provided on the light emitting surfaces of the individual LEDs that are on the stretched film.

### BRIEF DESCRIPTION OF THE DRAWINGS

FIGS. 1A-1G are cross-sections of light emitting devices according to various embodiments described herein.

FIGS. 2A-2B graphically illustrate performance data for light emitting devices according to various embodiments described herein.

FIGS. 3A-3C are cross-sections of light emitting devices according to various embodiments described herein during intermediate manufacturing steps.

FIG. 4 graphically illustrates performance data for light emitting devices according to various embodiments described herein.

FIGS. 5A-5B are photographs of light emitting devices according to various embodiments described herein.

FIGS. 6A-6D are photographs of light emitting devices according to other embodiments described herein.

FIG. 7 is a photograph of light emitting devices according to yet other embodiments described herein.

FIGS. 8A-8D graphically illustrate performance data for light emitting devices according to various embodiments described herein,

FIGS. 9A-9B graphically illustrate performance data for light emitting devices according to other embodiments described herein,

FIG. 10 graphically illustrates performance data for light emitting devices according to yet other embodiments described herein.

FIG. 11 graphically illustrates performance data for light emitting devices according to yet other embodiments described herein.

FIG. 12 graphically illustrates performance data for light emitting devices according to yet other embodiments described herein.

FIG. 13 graphically illustrates performance data for light emitting devices according to yet other embodiments described herein.

FIGS. 14A-14D are photographs of light emitting devices according to various embodiments described herein.

FIG. 15 graphically illustrates performance data for light emitting devices according to various embodiments described herein.

FIG. 16 graphically illustrates performance data for light emitting devices according to other embodiments described herein.

FIG. 17 graphically illustrates performance data for light emitting devices according to yet other embodiments described herein.

### DETAILED DESCRIPTION

The present invention now will be described more fully with reference to the accompanying drawings, in which various embodiments are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” another element, it can be directly on the other element or intervening elements may also be present. Furthermore, relative terms such as “beneath” or “overlies” may be used herein to describe a relationship of one layer or region to another layer or region relative to a substrate or base layer as illustrated in the figures. It will be understood that these terms are intended to encompass different orientations of the device in addition to the orientation depicted in the figures. Finally, the term “directly” means that there are no intervening elements. As used herein, the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” (and variants thereof) when used herein, specify the presence of stated features, integers, steps, operations, elements, and/or components, but do not preclude the presence or addition of one or more other features, integers, steps, operations, elements, components, and/or groups thereof. In contrast, the term “consisting of” (and variants thereof) when used in this specification, specifies the stated features, integers, steps, operations, elements, and/or components, and precludes additional features, integers, steps, operations, elements and/or components. Moreover, the term “consisting essentially of” when used in the specification, specifies the stated number of features, integers, steps, operations, elements and/or components, and precludes additional features, integers, steps, operations, elements and/or components, except for insubstantial amounts of impurities.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional and/or other illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a region illustrated or described as a rectangle will, typically, have rounded or curved features due to normal manufacturing tolerances. Thus, the regions illustrated in the figures are schematic in nature and their shapes are not intended to illustrate the precise shape of a region of a device and are not intended to limit the scope of the invention, unless otherwise defined herein.

Unless otherwise defined herein, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Some embodiments now will be described generally with reference to gallium nitride (GaN)-based light emitting diodes on silicon carbide (SiC)-based growth substrates for ease of understanding the description herein. However, it will be understood by those having skill in the art that other embodiments of the present invention may be based on a variety of different combinations of growth substrate and epitaxial layers. For example, combinations can include AlGaInP diodes on GaP growth substrates; InGaAs diodes on GaAs growth substrates; AlGaAs diodes on GaAs growth substrates; SiC diodes on SiC or sapphire (Al₂O₃) growth substrates and/or a Group III-nitride-based diode on gallium nitride, silicon carbide, aluminum nitride, sapphire, zinc oxide and/or other growth substrates. Moreover, in other embodiments, a growth substrate may not be present in the finished product. For example, the growth substrate may be removed after forming the light emitting diode, and/or a bonded substrate may be provided on the light emitting diode after removing the growth substrate. In some embodiments, the light emitting diodes may be gallium nitride-based LED devices manufactured and sold by Cree, Inc. of Durham, N.C.

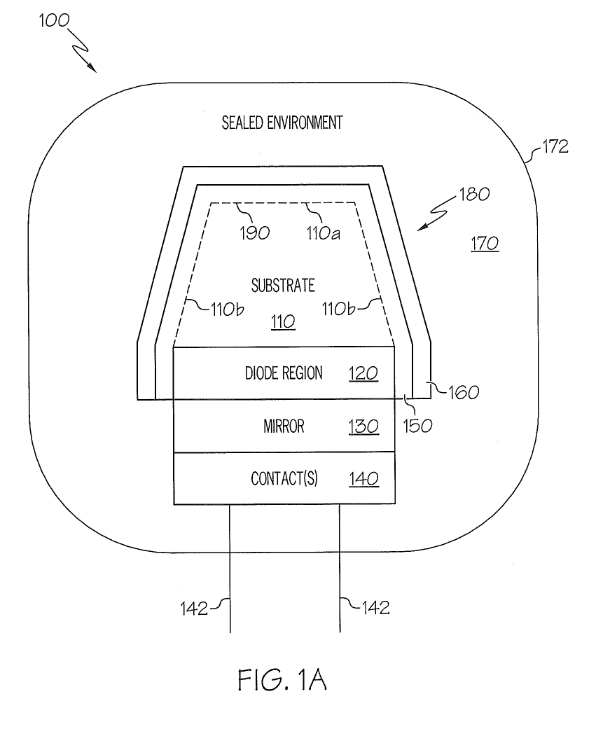

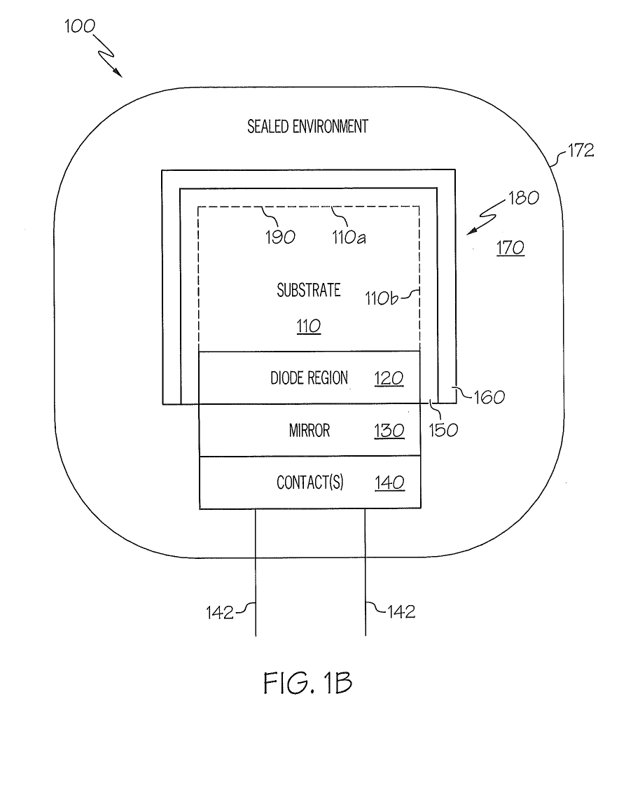

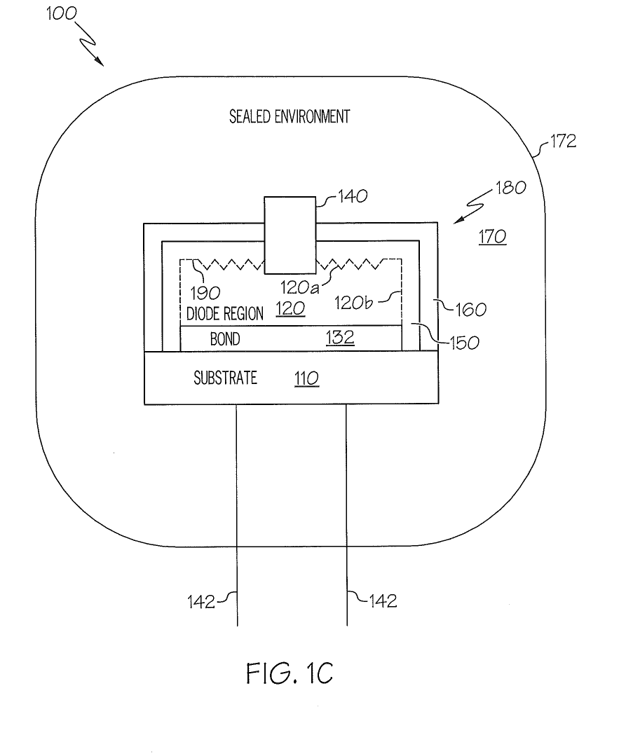

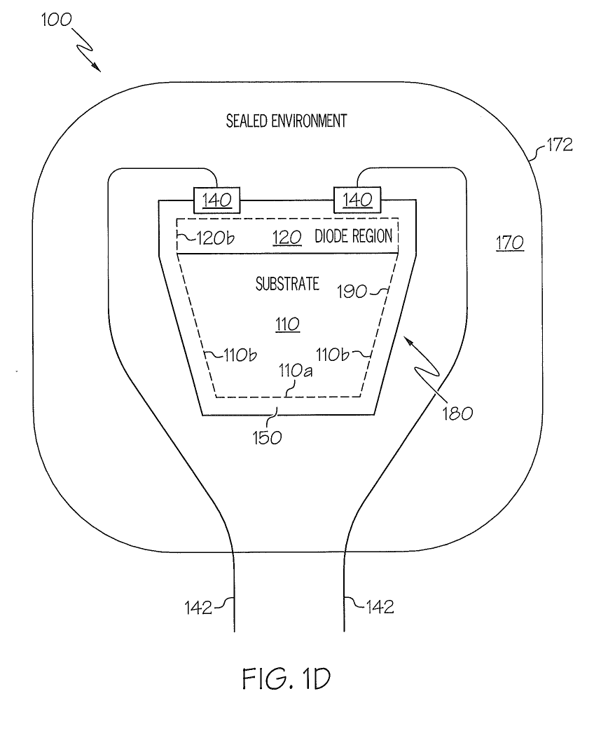

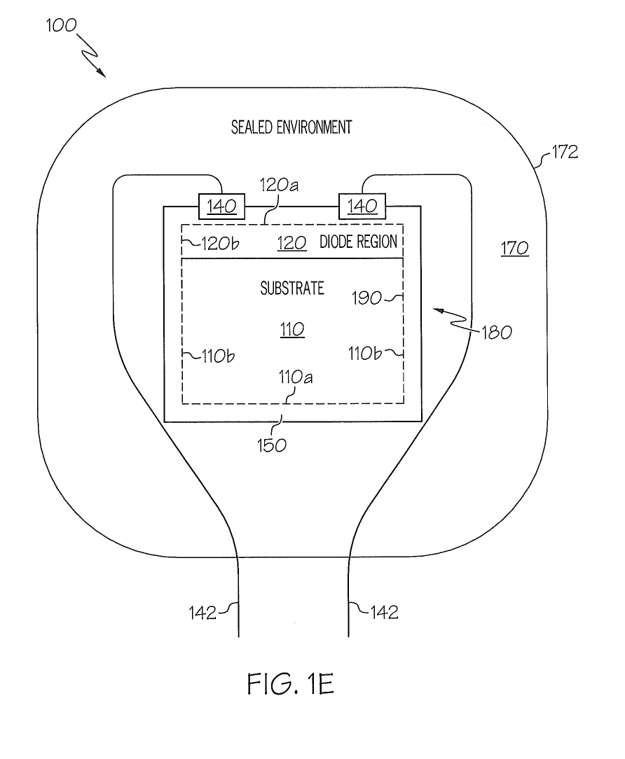

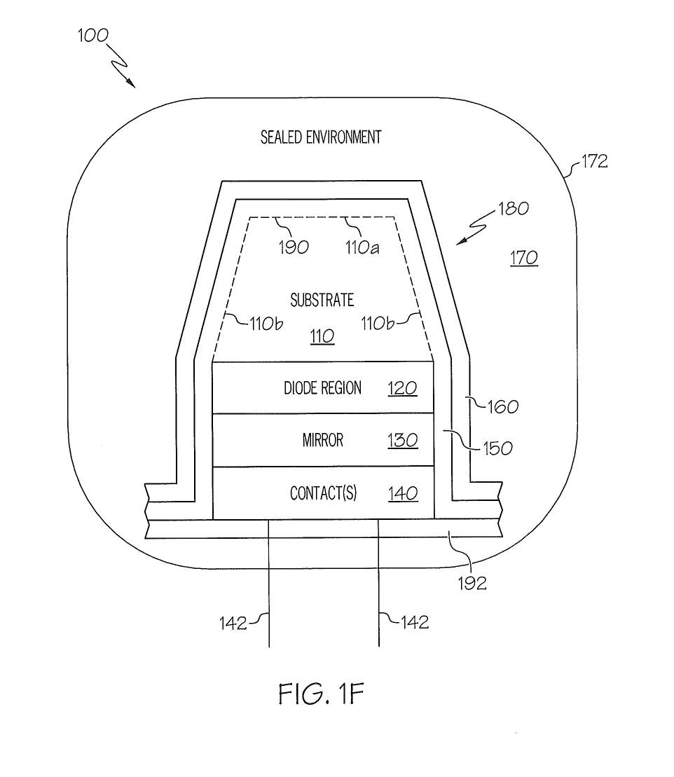

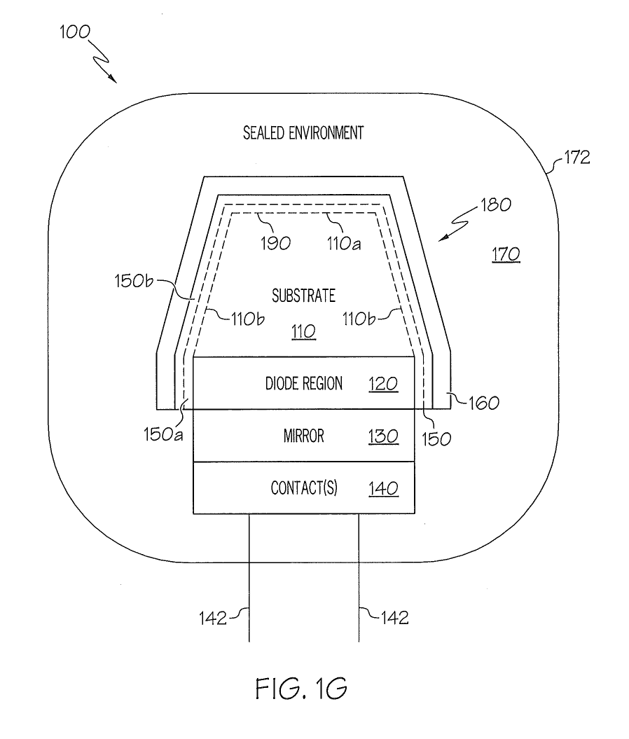

FIGS. 1A-1G are cross-sectional views of light emitting devices according to various embodiments described herein. Referring to FIG. 1A, a light emitting device 100 comprises an LED 180 that includes a light emitting surface 190, indicated herein by a dashed line. As used herein, a “light emitting surface” 190 is an outer surface of an LED through which photons that are generated by an LED diode region pass to external of the LED. A light emitting surface is free of (i.e., does not include) an opaque region thereon, wherein an opaque region can comprise, for example, a photon absorbing contact or a reflective surface (mirror).

Still referring to FIG. 1A, the LED 180 of FIG. 1A includes a substrate 110 and a diode region 120. The diode region may comprise a plurality of semiconductor layers that are configured to generate light, and may include therein an n-type layer and a p-type layer. Other layers or regions may be provided, which may include quantum wells, buffer layers, etc., that need not be described herein. Moreover, the n-type layer and the p-type layer may be adjacent one another, to form a p-n junction, or may be spaced apart from one another. Either or both layers may be at a surface of the diode region, or may be buried within the diode region. The diode region 120 also may be referred to herein as an “LED epi region” or simply as an “LED epi”, because it is typically formed epitaxially on a substrate 110. For example, a Group III-nitride based LED epi 120 may be formed on a silicon carbide growth substrate. In some embodiments, the growth substrate may be present in the finished product. In other embodiments, the growth substrate may be thinned or removed. In still other embodiments, another substrate may be provided that is different from the growth substrate, and the other substrate may be bonded to the LED after removing the growth substrate.

As shown in FIG. 1A, the substrate 110 includes a substrate face 110a remote from the diode region 120, and at least one substrate sidewall 110b between the substrate face 110a and the diode region 120. A mirror 130 may be provided on the diode region 120 to reflect light emerging from the diode region back into the diode region 120 and into the substrate 110. One or more LED contacts 140 may be provided on the mirror 130, and external device contacts 142 may also be provided. In some embodiments, the diode region comprises Group-III nitride-based semiconductor layers and the substrate 110 comprises silicon carbide.

FIG. 1A illustrates LEDs 180 that are configured for flip-chip mounting on a mounting substrate, such as a submount or other carrier. Various configurations of flip-chip mounted LEDs may be used in various embodiments described herein. Some of these embodiments are described, for example, in U.S. patent application Ser. No. 13/369,996 to Donofrio, entitled Gel Underfill Layers for Light Emitting Diodes and Methods of Fabricating Same, filed Feb. 9, 2012, assigned to the assignee of the present application, the disclosure of which is hereby incorporated herein by reference in its entirety as if set forth fully herein. These flip-chip LEDs may also be embodied by DA3547, DA700 and/or DA1000 LED chips marketed by Cree, Inc., and described in the respective Data Sheets entitled “Direct Attach DA3547™ LEDs” (Data Sheet: CPR3EL Rev. A, 2010), “Direct Attach DA700™ LEDs” (Data Sheet: CPR3EU Rev. -, 2011) and “Direct Attach DA1000™ LEDs” (Data Sheet: CPR3ES Rev. A, 2010), the disclosures of which are hereby incorporated herein by reference in their entirety as if set forth fully herein.

Still referring to FIG. 1A, a substance blocking or impermeable layer 150, which may be embodied as a silicon nitride layer, is provided on, and in some embodiments directly on and covering, and in other embodiments directly on and completely covering, the substrate face 110a and the at least one sidewall 110b. In other embodiments, when the light emitting surface further comprises at least one diode region sidewall 120a, the substance blocking layer 150, which in some embodiments may be a silicon nitride layer, may be provided on the diode region sidewall(s) 120b as well. The substance blocking layer 150 may be a carbon blocking layer, a volatile organic compound blocking layer and/or a moisture blocking layer, according to various embodiments described herein. The substance blocking or impermeable layer 150 may be embodied as a single layer, as illustrated in FIG. 1A, or as a plurality of sublayers, two of which 150a and 150b are illustrated in FIG. 1G. The sublayers may comprise, in some embodiments, silicon nitride and silicon dioxide, and a graded layer of silicon dioxide and silicon nitride may be provided therebetween, and/or a plurality of alternating silicon nitride and silicon dioxide layers may be provided. Other materials may also be used. For example, materials that are used as moisture barriers for Organic Light Emitting Diodes (OLEDs) may also be used in a single layer or multiple sublayer configurations. Examples of two layer configurations may include inorganic/inorganic (SiN/SiO₂, Al₂O₃), organic/inorganic, polymer/Al₂O₃, etc. sublayers. These materials may be selected for their photochemical properties, as well as their substance (such as water vapor) blocking properties.

A sealed environment 170 may be provided surrounding the light emitting surface 190. The sealed environment 170 may be maintained by a bulb 172 or other housing. In some embodiments, the sealed environment may comprise a sealed gaseous environment. In other embodiments, the sealed environment may include a liquid cooled environment, as well.

As used herein, a “sealed gaseous environment” means an environment that confines and encloses gas within the environment and blocks external gasses from entering the environment. It will be understood that a sealed gaseous environment may provide some gas leakage over extended time periods. In some embodiments, the sealed gaseous environment may consist essentially of helium gas, which is an inert gas having good thermal conductivity. The helium gas may include impurities therein, including carbon in the form of Volatile Organic Compounds (VOCs). In other embodiments, the sealed gaseous environment comprises less oxygen than air and/or more helium than air. In yet other embodiments, the sealed gaseous environment is substantially free of oxygen. In still other embodiments, it may be desirable to maintain the helium percentage as high as possible for thermal effects, and it may also be desirable to include low single digit percent oxygen, with the concentration of oxygen being low enough so as not to have a significant impact on the thermal performance. Also, in many applications where the sealed environment is air, limiting the photocatalytic activity of the surfaces may also be of value. Specifically, in devices that are run with some oxygen, there appears to be development of precipitation and other deposits on the light emitting surface. This can be a performance issue, an aesthetic issue, or both.

Finally, referring to FIG. 1A, a phosphor layer 160 may be provided on the substance blocking layer 150, such as the silicon nitride layer. The phosphor layer may comprise a silicone with phosphor particles therein. In other embodiments, a sublayer comprising silicone and phosphor may be provided adjacent the light emitting surface 190 and a silicone sublayer that is free of phosphor may be provided remote from the light emitting surface 190. The phosphor layer 160 may be conformal as illustrated in FIG. 1A, or may be non-conformal and may be shaped, for example, as a dome or lens. It will be understood that the term “phosphor” is used herein to indicate any wavelength conversion material.

Various embodiments of phosphor layers 160 and diode regions 120 may be provided. For example, in some embodiments, the diode region 120 is configured to emit blue light, for example light having a dominant wavelength of about 450-460 nm, and the phosphor layer 160 comprises yellow phosphor, such as YAG:Ce phosphor having a peak wavelength of about 550 nm. In other embodiments, the diode region 120 is configured to emit blue light upon energization thereof, as described above, and the phosphor layer 160 may comprise a mixture of yellow phosphor and red phosphor, such as a CASN-based phosphor. In still other embodiments, the diode region 120 is configured to emit blue light upon energization thereof, and the phosphor layer 160 may comprise a mixture of yellow phosphor, red phosphor and green phosphor, such as LuAG:Ce phosphor particles. Moreover, various combinations and subcombinations of these and/or other colors and/or types of phosphors may be used in mixtures and/or in separate layers. Various techniques may be used to apply the phosphor, including spraying, coating and/or other techniques. Phosphor preforms also may be applied.

In FIG. 1A, the substrate 110 includes beveled sidewalls 110b. In contrast, in embodiments of FIG. 1B, the sidewalls 110b are orthogonal to the substrate face 110a. In some embodiments of FIG. 1A, the substrate may be silicon carbide, whereas in some embodiments of FIG. 1B, the substrate 110 may comprise sapphire (Al₂O₃). Embodiments of FIG. 1B may be embodied by an OSRAM Oslon LED.

FIG. 1C illustrates other embodiments in which the growth substrate for the diode region 120 is removed and, instead, a carrier or mounting substrate 110 is provided. A bond 132 bonds the diode region 120 to the carrier substrate 110. In these embodiments, the light emitting surface 190 may include a face 120a of the diode region 120 that is remote from the carrier substrate 110, and a sidewall 120b of the diode region 120. In these embodiments, the carrier substrate 110 may comprise silicon and the remote face 120a of the diode region 120 may be textured. A top contact 140 may be provided, as may be a bottom contact (not shown). FIG. 1C may be embodied by Cree EZ500, EZ600, EZ900, EZ1000 and EZ1400 LEDs, as described in the Data Sheets entitled “Cree® EZ500™ Gen II LED” (Data Sheet: CPR3EB Rev. -, 2009), “Cree® EZ600™ Gen II LED” (Data Sheet: CPR3EE Rev. A, 2010), “Cree® EZ900™ Gen II LEDs” (Data Sheet: CPR3DX Rev. B, 2008-2011), “Cree® EZ1000™ Gen II LEDs” (Data Sheet: CPR3EC Rev. A, 2009) and “Cree® EZ1400™ Gen II LEDs” (Data Sheet: CPR3EK Rev. -, 2010), the disclosures of which are hereby incorporated herein by reference in their entirety as if set forth fully herein.

FIGS. 1A-1C illustrate light emitting diodes that are configured for flip- chip mounting on a mounting substrate. Various configurations of flip-chip mounted light emitting diode dies may be used in various embodiments described herein. Other light emitting devices according to various embodiments described herein may be configured for non-flip-chip mounting on a mounting substrate, as described and illustrated, for example, in U.S. Patent Application Publication 2011/0031502 to Bergmann et al. entitled “Light Emitting Diodes Including Integrated Backside Reflector and Die Attach”, filed Aug. 10, 2009, assigned to the assignee of the present application, the disclosure of which is hereby incorporated herein by reference in its entirety as if set forth fully herein. Moreover, other light emitting devices according to various embodiments described herein may be configured as vertical light emitting devices, as described and illustrated, for example, in U.S. Pat. No. 6,791,119 to Slater, Jr et al., entitled “Light Emitting Diodes Including Modifications for Light Extraction”, filed Jan. 25, 2002, assigned to the assignee of the present application, the disclosure of which is hereby incorporated herein by reference in its entirety as if set forth fully herein.

FIG. 1D illustrates embodiments analogous to FIG. 1A, except that a mirror is not provided, so that the light emitting surface 190 includes the entire outer surface of the substrate 110 and diode region 120, except where the contacts 140 are present. The beveled substrate may comprise silicon carbide.

Finally, FIG. 1E illustrates embodiments analogous to FIG. 1B, except that a mirror 130 is not provided. The substrate may comprise sapphire.

In any of the embodiments of FIGS. 1A-1F, a sealed environment 170 is provided surrounding the light emitting surface 190, and the substance blocking layer 150, such as the silicon nitride layer, is provided on the light emitting surface 190. In some embodiments, the substance blocking layer 150 such as the silicon nitride layer, is directly on and entirely covers the entire light emitting surface 190, as was illustrated in FIGS. 1A-1F. In some embodiments, the silicon nitride layer may comprise stoichiometric silicon nitride that is about 0.5 μm thick. However, other thicknesses of silicon nitride may be used. The silicon nitride layer 150 may be deposited by Plasma-Enhanced Chemical Vapor Deposition (PECVD). Other techniques, such as sputtering, may also be used.

In embodiments of FIGS. 1A-1E and 1G, the substance blocking layer 150, such as a silicon nitride layer, and the phosphor layer 160 do not extend beyond the LED 180. However, in embodiments of FIG. 1F, the LED 180 may be mounted on a mounting substrate 192, such as a submount, a printed circuit board or other carrier that may comprise silicon, aluminum nitride and/or aluminum oxide. In these embodiments, the substance blocking layer 150 and/or the phosphor layer 160 may also extend onto the mounting substrate 192. In some embodiments, the substance blocking layer 150 and/or the phosphor layer 160 may be continuous layers that cover all of the exposed surface of the packaged LED. It will be understood that embodiments of FIG. 1F may be embodied with any of the embodiments of FIGS. 1A-1E or 1G and/or other LEDs according to various embodiments described herein. It will also be understood that in FIGS. 1A-1G, only a single LED 180 is illustrated in the sealed environment 170. However, in other embodiments, two or more LEDs, which may be identical or some or all of which may be different from one another, may be provided in a single sealed environment 170.

Additional discussion of various embodiments described herein will now be provided. Specifically, as was described above, it has heretofore been recognized that the presence of VOCs or other carbon-containing compounds in LED illumination systems may accelerate degradation or impair performance, and that chemical incompatibility is often a localized phenomena occurring in sealed portions of the systems where LEDs operate at elevated temperatures, with little or no air movement. It has been theorized that the combination of light and heat allows volatile organic compounds to react with silicone and produce discoloration and surface damage. Moreover, in a sealed environment, it has been theorized that VOCs that were introduced during manufacture or assembly may permeate and remain in the silicone. Under heat and blue light, the VOCs inside the silicone may partially oxidize to create a silicone discoloration, particularly on the surface of the LED where the flux energy is highest. In contrast, in air-rich or open air environments, VOCs have a chance to leave the area, driven by the normal air flow. In fact, transferring the devices which were discolored in the enclosed environment back to open air may allow the oxidized VOCs to diffuse out of the silicone, and may restore the original optical properties of the LED.

Without wishing to be bound by any theory of operation, various embodiments described herein may arise from the apparent realization that the light emitting surface itself, rather than the silicone, provides a mechanism along the lines of a photocatalytic reaction, which breaks down the volatile organic compounds to produce carbon on the surface of the LEDs. Thus, rather than, or in addition to, attempting to improve the characteristics of the silicone and/or to reduce the amount of VOCs that are introduced into the sealed environment, various embodiments described herein can prevent volatile organic compounds from reaching the light emitting surface of the LED, where they are then subject to photocatalytic breakdown into carbon, which manifests itself as discoloration, browning or charring at the light emitting surface. In a gaseous environment that contains oxygen, the photocatalyzed carbon may react with the oxygen to produce carbon dioxide. However, in a sealed gaseous environment, there may insufficient oxygen present to allow this additional reaction to take place.

Accordingly, some embodiments described herein can provide a carbon blocking layer, such as a silicon nitride layer, directly on and completely covering the light emitting surface of the LED. The carbon blocking layer can prevent the photocatalytic reaction from taking place at the light emitting surface, by preventing carbon from reaching the light emitting surface. In other embodiments, the carbon blocking layer can impede carbon from reaching the light emitting surface without completely blocking the carbon. Moreover, in other embodiments, the substance blocking layer may comprise other materials, such as boron nitride, in addition to or instead of silicon nitride. The substance blocking layer may also comprise multiple sublayers. The sublayers may comprise, in some embodiments, silicon nitride and silicon dioxide, and a graded layer of silicon dioxide and silicon nitride may be provided therebetween, and/or a plurality of alternating silicon nitride and silicon dioxide layers may be provided. Various layers and/or sublayers may be used to provide a desired index of refraction or change in an index of refraction. Other materials may also be used. For example, materials that are used as moisture barriers for Organic Light Emitting Diodes (OLEDs) may also be used in a single layer or multiple sublayer configurations. Examples of two layer configurations may include inorganic/inorganic (SiN/SiO₂, Al₂O₃), organic/inorganic, polymer/Al₂O₃, etc. sublayers. These materials may be selected for their photochemical and/or optical properties, as well as their substance (such as water vapor) blocking properties.

Without wishing to be bound by any theory of operation, various embodiments described herein may also or alternatively arise from the apparent realization that the silicon nitride layer may act as a moisture barrier. This may be the main reason it appears to work well relative to PECVD SiO₂, which is moisture permeable. One of the primary mechanisms for the catalytic process is the formation of OH-radicals from water molecules reacting on the surface. Although this is not an entirely understood process, there are also potentially several mechanisms at play in the surface chemistry that may include direct reaction without the need for the OH-radicals. However, this direct reaction does not appear to be well recognized in the literature. Water Vapor Transmission Rate (WVTR) may be used to quantify this reaction. The literature appears to indicate that this direct reaction may occur with a semiconducting hole, without the need for an intervening OH-radical. Since the destruction of the semiconducting hole entails the transfer of an electron to the particle from its environment, the particle must remain nearly electrically neutral or it will repel additional electrons. It is thought in the literature that molecular oxygen (O₂) is reduced to form the radical O₂, which allows excess electrons to exit the particle.

Without wishing to be bound by any theory of operation, various embodiments described herein may also arise from the apparent realization that the phosphor particles in the phosphor layer may also be acting as a photocatalytic source, in addition to or instead of the light emitting surface of the LED. This may be the case because the observed degradation of the LED appears to change when a phosphor layer is added to the LED, even when a substance blocking layer is included directly on the light emitting surface. Conventional phosphors, such as YAG:Ce phosphors, may include Y₃Al₅O₃, which may be chemically similar enough to sapphire (Al₂O₃), so as to exhibit photocatalytic behavior. If photocatalytic behavior is exhibited by the phosphor particles themselves, other embodiments of a substance blocking layer, such as a carbon blocking layer or a moisture blocking layer, may comprise a coating, such as a silicon nitride coating, that is applied to the phosphor particles in addition to or instead of being applied to the light emitting surface. Various conventional coating techniques that are used for powders may be used to coat the individual phosphor particles with silicon nitride and/or another substance blocking layer. In yet other embodiments, in addition, or in the alternative, a substance blocking binder may be used for the phosphor particles, that is different from the conventional silicone phosphor binder, so as to encapsulate the phosphor particles and, in some embodiments, to act as a substance blocking layer for both the phosphor particles and the light emitting surface. In some embodiments, a polymer phosphor binder may be used. It will be understood that any such substance blocking phosphor particle coating or substance blocking phosphor particle binder should be highly transparent in the visible spectrum, in addition to having the desired surface properties, carbon and/or moisture blocking capability, photo/thermal stability, etc.

It would not be predictable to use a silicon nitride layer directly on and completely covering the light emitting surface of an LED. Specifically, silicon dioxide has been heretofore used to encapsulate a light emitting surface of an LED. A layer of silicon dioxide is almost 100% transparent to visible light. In contrast, silicon nitride, while being transparent, still allows appreciable light absorption. For example, a layer of silicon nitride about 0.5 μm thick may absorb about 2% of the incoming visible light. Other reasons may also explain the absorption/loss mechanism of the silicon nitride. Thus, it would not be predictable to apply a more optically absorbing layer (silicon nitride) rather than an almost completely transparent layer (silicon dioxide) to encapsulate the light emitting surface. Yet, various embodiments described herein have found that silicon dioxide is relatively ineffective in preventing discoloration of LEDs in a sealed environment. In contrast, a silicon nitride layer can greatly reduce or eliminate discoloration at the light emitting surface of the LED in a sealed gaseous environment.

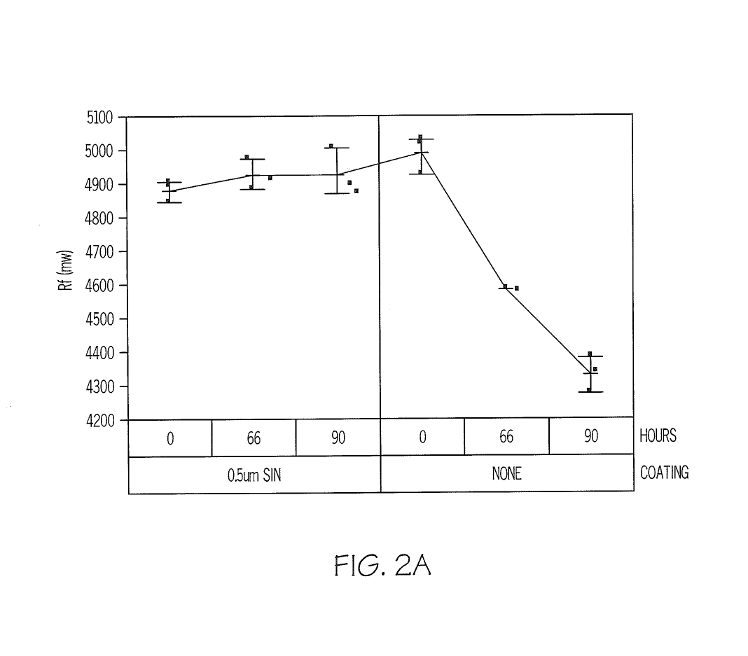

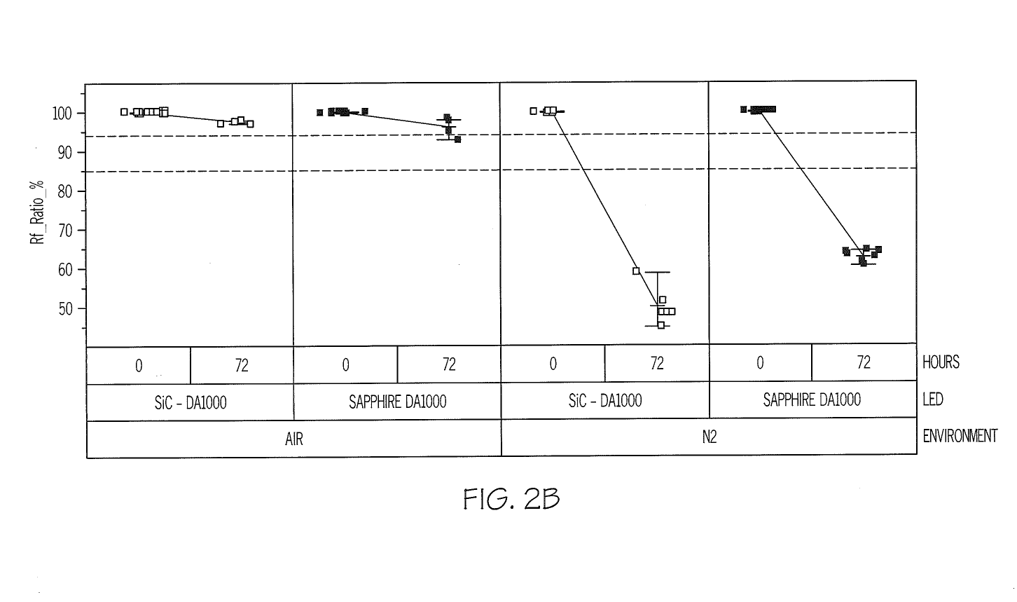

FIGS. 2A and 2B illustrate the efficacy of a substance blocking layer according to various embodiments described herein. In FIG. 2A, data is illustrated for a Cree DA500 (500 μm×500 μm in size) active region that is on a sapphire substrate that is coated with a silicone layer (no phosphor) and is present in a sealed gaseous environment consisting essentially of 100% helium. As shown at the left of FIG. 2A, when a 0.5 μm silicon nitride coating is present on the light emitting surface (the sapphire substrate), no appreciable degradation in Radiant Flux (RF), measured in mW, takes place for 90 hours in the sealed gaseous environment. In sharp contrast, when a silicon nitride coating is absent, significant degradation in radiant flux, measured by a radiant flux ratio as a percent, takes place over the period of 90 hours. FIG. 2B graphically illustrates Cree DA1000 chips that are bare (no silicone layer) that are exposed to air, or that are contained in a nitrogen sealed gaseous environment. As shown at the left side of FIG. 2B, in air (non-sealed environment), little degradation takes place for either a silicon carbide (SiC) or sapphire (Al₂O₃) substrate. In contrast, on the right side, the uncoated LEDs experience significant degradation in a sealed gaseous environment.

Accordingly, FIGS. 2A and 2B demonstrate that a substance blocking layer, such as a 0.5 μm thick silicon nitride layer, can change the surface properties of the light emitting surface and can reduce or eliminate browning or charring in a sealed gaseous environment. All types of LED structures, such as silicon carbide, gallium nitride and sapphire, appear to demonstrate this behavior. Moreover, even though the number of hours in FIGS. 2A and 2B is not very long, FIGS. 2A and 2B illustrate a high degree of efficacy in an inert environment with known carbon contaminants. In some embodiments, the use of a silicon nitride layer can reduce or eliminate the need to further refine the properties of the silicone layer.

Techniques for manufacturing LEDs according to various embodiments described herein will now be described. Conventionally, LEDs are manufactured as wafers and then singulated into individual LED devices. When the light emitting surface is only at the top surface of the wafer, a silicon nitride layer or other substance blocking layer according to various embodiments described herein may be formed on the top (exposed) surface of the wafer during wafer fabrication. However, in other embodiments, the light emitting surface includes sidewalls of the substrate and/or the diode region. In these cases, since the sidewalls are not exposed during wafer fabrication, at least a portion of the silicon nitride layer may be formed on the LEDs after singulating the individual LEDs in the wafer. Thus, a light emitting device may be fabricated by providing a wafer including therein a plurality of LEDs, a respective one of which includes a light emitting surface; singulating the individual LEDs in the wafer; and forming a silicon nitride layer or other substance blocking layer on the light emitting surfaces of the individual LEDs that were singulated.

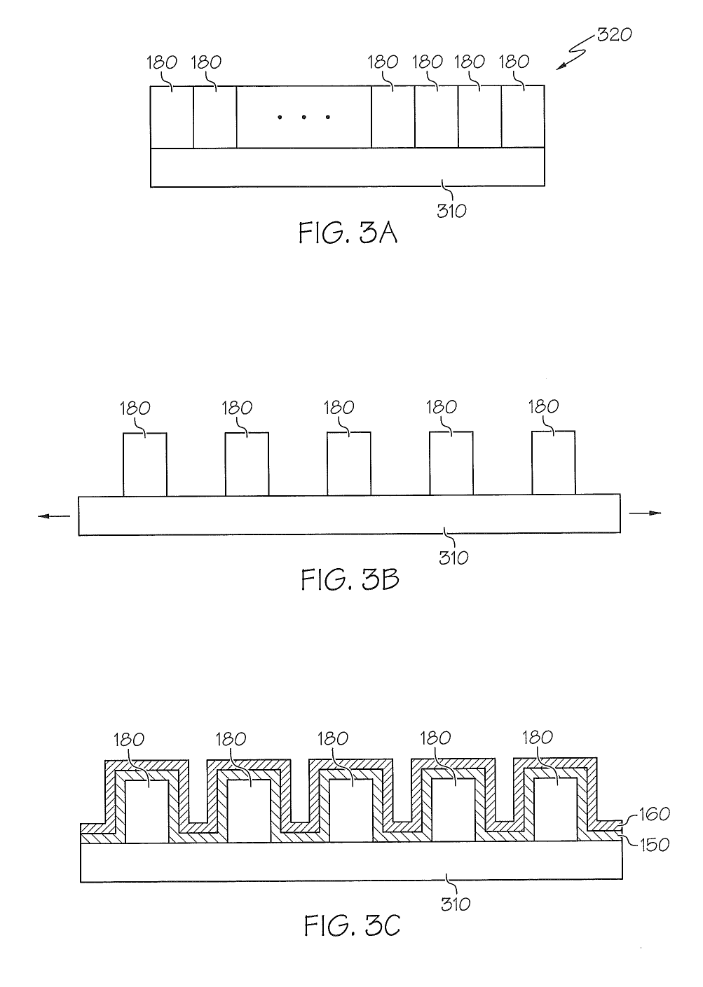

FIGS. 3A-3C illustrate methods of fabricating light emitting devices according to various embodiments described herein. Referring to FIG. 3A, a wafer 320, including therein a plurality of LEDs 180, is provided along with a stretchable film 310 on a face thereof. In other embodiments, another temporary carrier is used that can withstand the temperatures and/or other process conditions that are involved. The LEDs 180 are singulated as shown by the lines between the LEDs 180, using a conventional saw blade, laser and/or other conventional techniques.

Then, referring to FIG. 3B, the stretchable tape 310 is stretched along the direction of the arrows in FIG. 3B, to expose the sidewalls of the LEDs 180. As illustrated in FIG. 3C, a silicon nitride layer 150 is then provided, for example using plasma-enhanced chemical vapor deposition (PECVD). A silicone-containing layer 160 may also be provided. In other embodiments, the silicon nitride or other substance blocking layer 150 may be provided on the top surface of the LEDs while in wafer form, and may be provided on the sidewalls after singulation.

Further discussion of various embodiments described herein will now be provided. Without wishing to be bound by any theory of operation, various embodiments described herein may arise from a recognition that discoloration or charring, such as browning, of an LED in a sealed gaseous environment appears to be due to the breakdown of carbon compounds at the light emitting surface. Specifically, electron diffraction data shows higher carbon levels on the surface of degraded components relative to sister parts not run in an inert atmosphere, where there is no contamination already on the component. Moreover, gas analysis shows the formation of byproducts, such as CO₂, H₂O, etc., consistent with the breakdown and oxidization of carbon compounds. Silicone itself and its additives are potential sources of carbon compounds subject to breakdown, and stability and breakdown may be different than other carbon contaminants in the inert atmosphere. Other sources of VOCs are also present, based on bare LED die results. For example, the die attachment flux and/or the component solder flux, may be a source of VOCs, as may be the type of flux clean that is employed. The board dielectric/solder mask may also be a source VOCs, and other components may also be a source VOCs. The degradation rate appears to be faster without silicone.

It has been found, according to various embodiments described herein, that surface treatments or coatings on bare blue LED dies can reduce the degradation rate and reduce or eliminate the darkening seen on the package floor and/or solder mask. Moreover, silicone types and compositions also appear to be factors. For example, a methyl vs. phenyl silicone, the use or absence of an adhesion promoter, etc., may also be a factor. Physical properties, such as permeability of the silicone, may also be a factor. However, the fundamental mechanism has heretofore been largely explained, particularly with regard to the question of the interfacial/surface nature of the carbon deposits. Specifically, a flux density/Inverse Square Law relationship does not appear to be present, as demonstrated by LEDs with and without silicone. Moreover, the dark residue is not only seen at the light emitting surface, but is also seen at the interfaces to the solder mask on the floor where the flux density is significantly lower. These regions are also readily oxidized on burn-in in atmosphere. Moreover, no significant gradient to the discoloration in the silicone is typically seen on a scale visible in an optical microscope.

Various embodiments described herein may arise from a recognition that visible spectrum LEDs may be highly efficient at breaking down and oxidizing VOCs. Specifically, an array of bare blue spectrum LED chips running at fairly low power at elevated temperature would seem to be effective at breaking down and oxidizing VOCs.

Prior investigations have been conducted in the art regarding photocatalytic decomposition and oxidation of VOCs. Most of this prior work appears to have focused on UV sources that use TiO₂ (which may be present in white solder masks) and doped variants as a catalyst. Other references, however, have also investigated visible wavelength LEDs, as well as blue LEDs used with a visible spectrum responsive catalyst. Most photocatalysts are wide bandgap n-type semiconductors or metal oxides. Accordingly, it now appears that all the elements already exist in a typical LED component to break down and oxidize carbon compounds without a secondary catalyst. Specifically, LEDs have the added elements of heat and electrical fields versus the use of a passive catalyst. These references generally plot CO₂ generation versus a reduction in the carbon species of interest. This is consistent with what appears to be taking place in a sealed environment according to various embodiments described herein. Accordingly, a photocatalytic decomposition and oxidation of VOCs may explain the interfacial/surface nature of the breakdown/deposits.

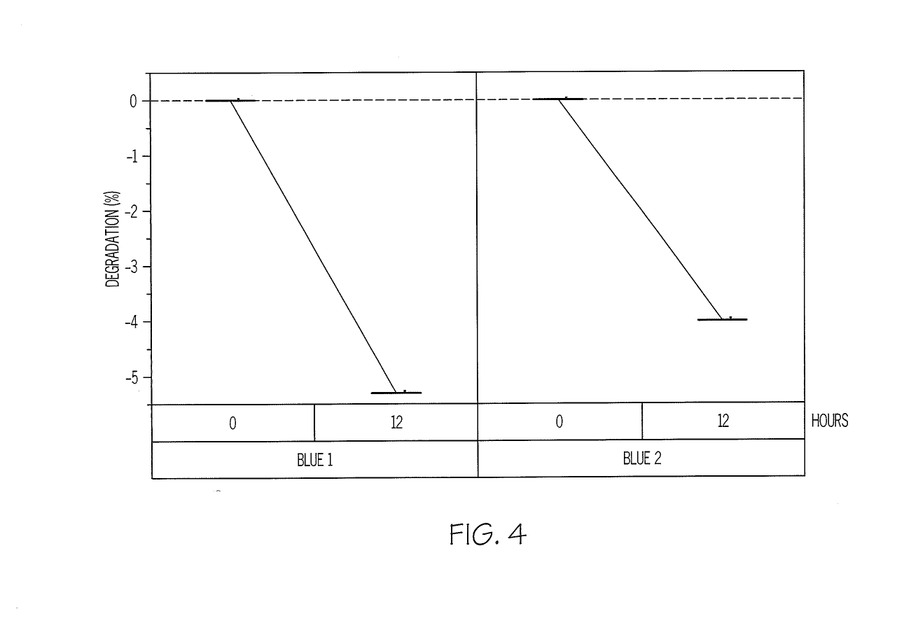

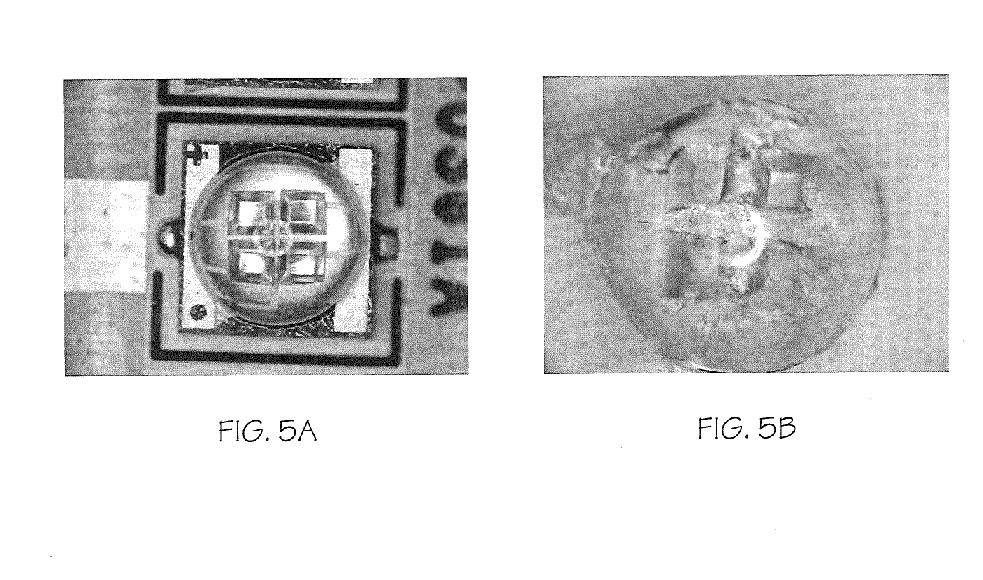

FIG. 4 graphically illustrates degradation of two blue LEDs that include a phenyl dome thereon, that does not contain phosphor or gel. These devices show degradation and visible browning at the device interface, as shown in FIG. 5A. The degradation rate was slower than that seen in current testing with no silicone. Moreover, as shown in FIG. 5B, some portions of the facets in the removed lens show the interfacial discoloration, which does not extend into the bulk silicone.

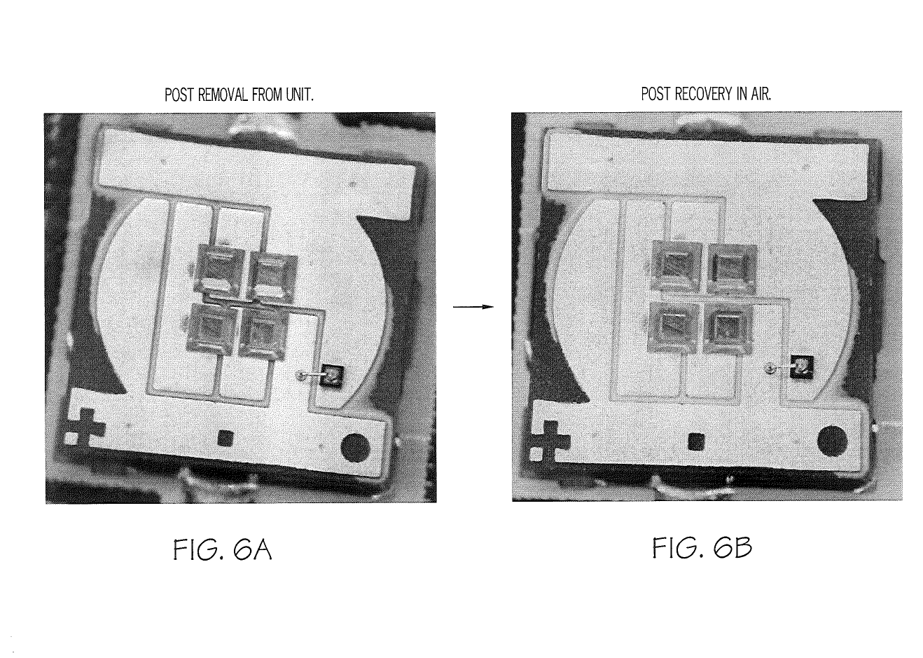

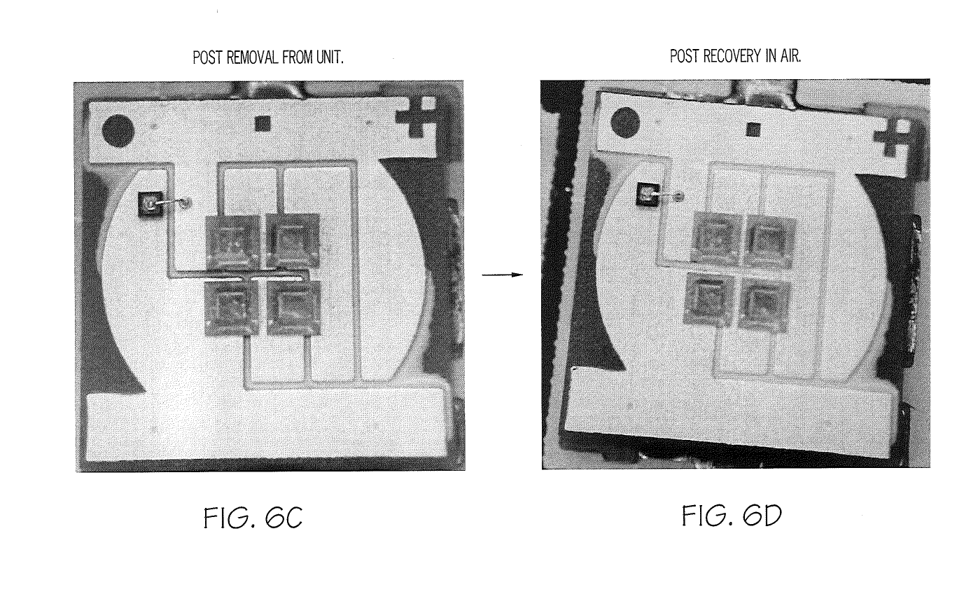

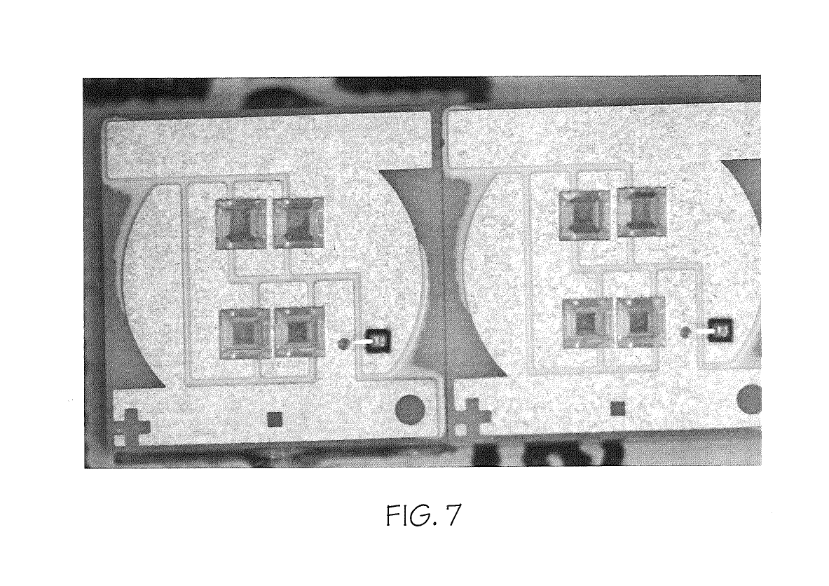

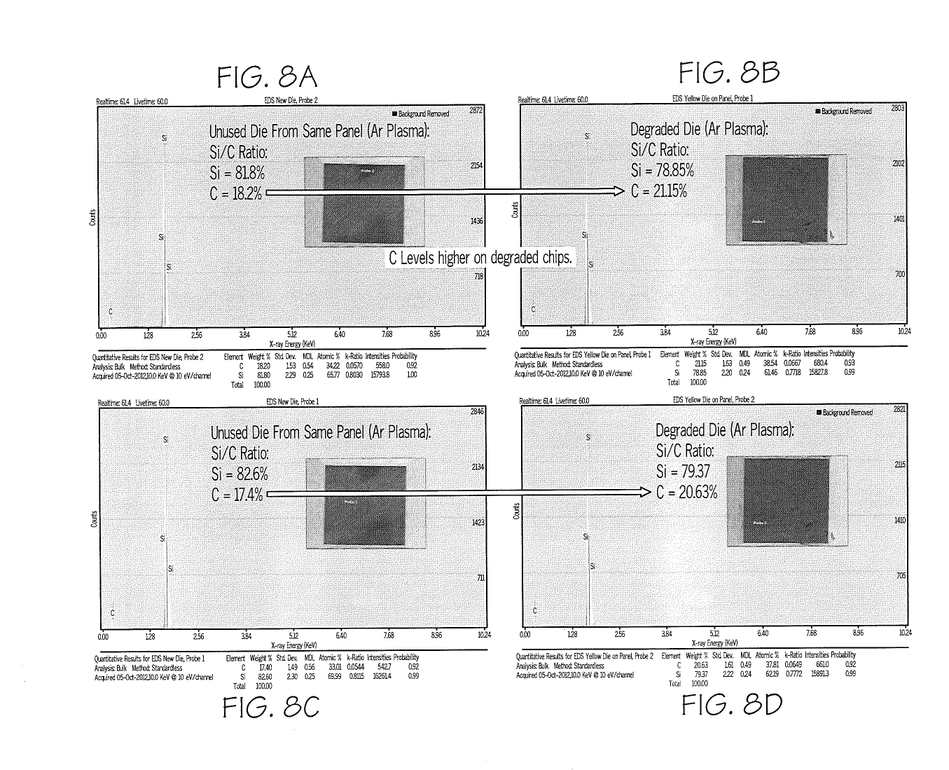

FIGS. 6A and 6C illustrate blue-only parts that showed significant discoloration and degradation of over 20% when operated in an inert environment for about 16 hours. FIGS. 6B and 6D illustrate that the degradation was recoverable on burn-in in the presence of oxygen. As shown, solder mark discoloration is completely eliminated, with some discoloration of the silver remaining. Moreover, the recovered parts showed a similar degradation in a unit when resealed and run again. However, other data showed that degradation may be significantly lower the second time around. Moreover, scanning electron microscope/electron diffraction analysis showed increased carbon peaks in the dark area. The discolored silver also showed an increase in the copper peak.

FIG. 7 illustrates results when about 500 Å of PECVD silicon dioxide (SiO₂) was deposited on LEDs on a mounting substrate. As shown, solder mask darkening and discoloration around the base of the devices was also eliminated. Moreover, degradation at about 16 hours was significantly lower than when the SiO₂ layer was not present, but still showed a 14% loss. Comparing the left side of FIG. 7 to the right side of FIG. 7, devices appear to be darker (left side) than an unused part from the same panel (right side). The silver on the package also seems to have a different hue, as well. This different hue may be thermally induced, as some variation is seen in the silver appearance on components from the top row of the board versus the bottom row, with the top row being hotter.

Referring now to FIGS. 8A-8D, comparing an unused die (FIGS. 8A and 8C) to a degraded die from the same panel (FIGS. 8B and 8D) shows an increase in the level of carbon on degraded chips.

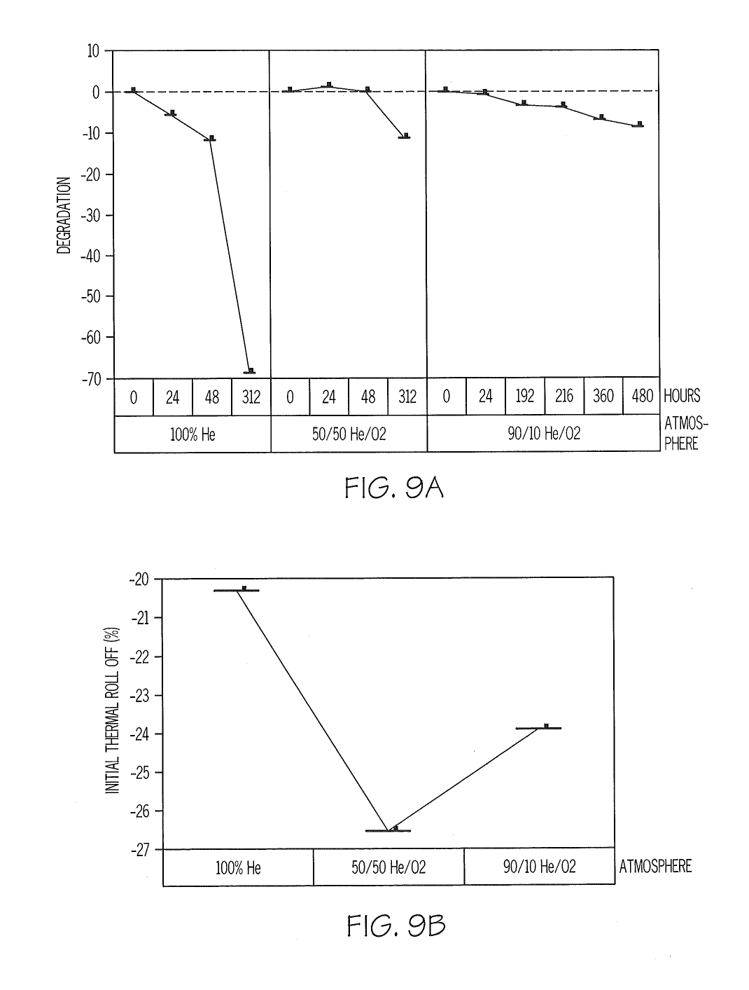

In FIGS. 9A and 9B, the effect of an adhesion promoter or lack of an adhesion promoter between the silicone and the light emitting surface is illustrated. Based on the interfacial nature that appears to be taking place in the degradation/browning, and statements from the manufacturer of adhesion promoters (for example The Dow Chemical Company) that their adhesion promoters are designed to migrate to the interfaces, an adhesion promoter-free version of silicone was tested. However, as shown in FIG. 9A, no significant improvement in the degradation was found compared to standard silicone that includes an adhesion promoter therein. Specifically, at the left side of FIG. 9A, an adhesion promoter-free silicone layer shows substantial degradation in 100% helium over 312 hours. The same device shows less degradation in a 50/50 helium/oxygen atmosphere and even less degradation in a 90/10 helium/oxygen atmosphere. Thus, degradation is significantly reduced with the addition of as little as 10% oxygen, but still not at acceptable levels. Moreover, as shown in FIG. 9B, the 50/50 helium/oxygen ratio causes the LED to run hotter, which may be likely factor in the increased degradation relative to the 90/10 ratio (right side of FIG. 9B).

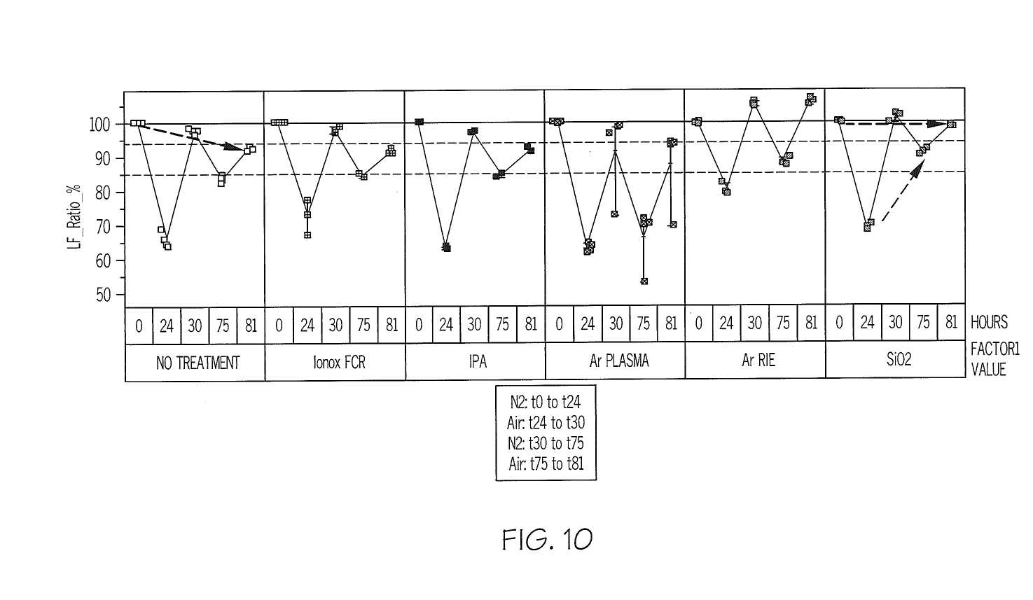

FIG. 10 illustrates degradation and recoveries under various types of treatment. In FIG. 10, blue LEDs without any silicone coating were tested. All show significant Luminous Flux (LF) roll-off in 24 hours. However, all exhibited good LF recovery when exposed to air within hours. There also appears to be less LF drop on a second nitrogen exposure, but still significant for untreated devices shown in the left column of FIG. 10 (17.7% drop; from 34.4% after the first nitrogen exposure). Silicon dioxide coated devices (extreme right of FIG. 10) showed significantly less drop on the second pass (9.1% drop; from 31.3% after the first nitrogen exposure). Thus, there is a much more complete recovery for silicon dioxide coated devices (98.5%—extreme right of FIG. 10) than uncoated devices (92.3%—extreme left of FIG. 10).

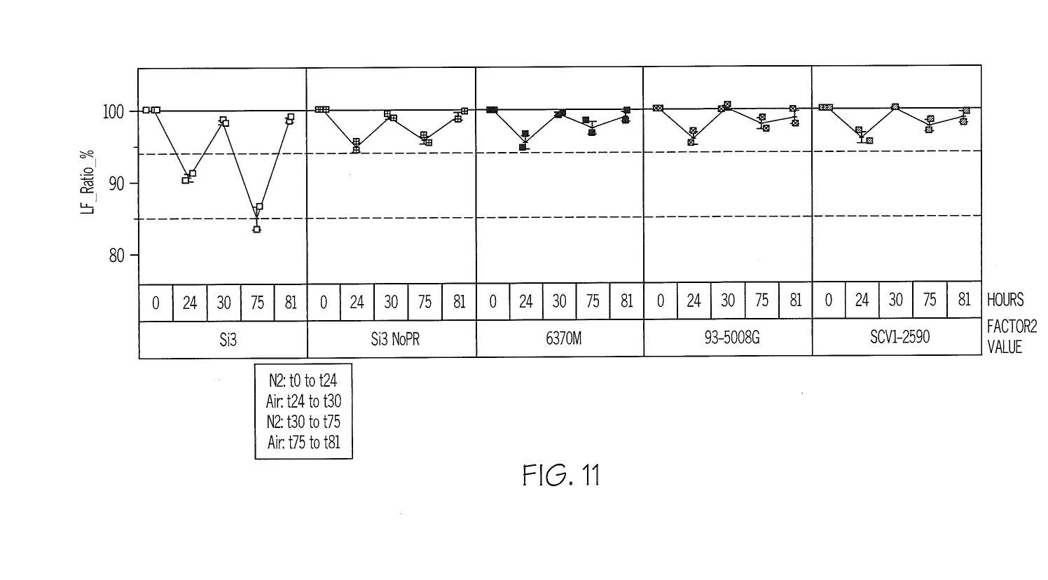

FIG. 11 repeats the same testing with a silicone coating that does and does not contain phosphor. These tests show that silicone without phosphor shows significantly less LF roll-off than silicone with phosphor, and in the same range as OE6370M. Thus, low volatile silicones are no better than standard silicones.

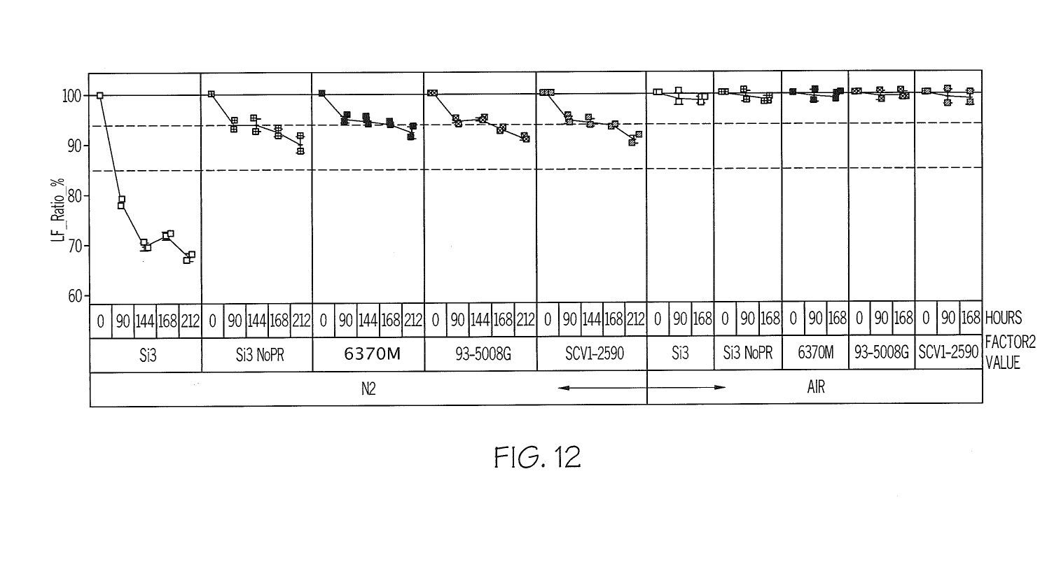

FIG. 12 extends this study to determine if low volatility silicone performs better than a standard silicone. As shown at the left, significant degradation still takes place in a nitrogen atmosphere, whereas at the right, very little degradation takes place in air.

It should also be noted, that while the data described and illustrated in connection with FIG. 9 showed that removing the adhesion promoter did not resolve the primary fail mode, the data of FIGS. 11 and 12 shows that removing the adhesion promoter can provide a benefit. It appears that the reactive compounds of the adhesion promoter are less stable and are potential carbon sources subject to breakdown. Permeability of the silicone is also a factor, so that the typically more stable methyl silicones showed faster degradation due to their higher permeability. Thus, FIGS. 11 and 12 showed that the structure that includes adhesion promoter degrades more than the structure without adhesion promoter. Basically, by removing the adhesion promoter, the silicone phosphor layer performs more similarly to low volatility methyl silicone, as shown in this data

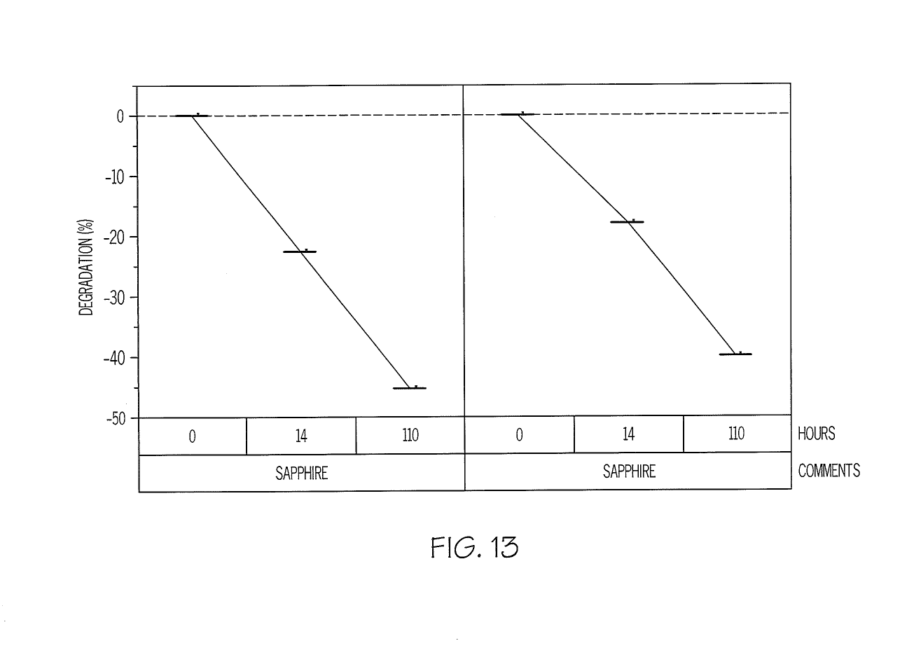

FIG. 13 graphically illustrates degradation of sapphire-based parts in helium in the presence of a silicone phenyl or methyl dome.

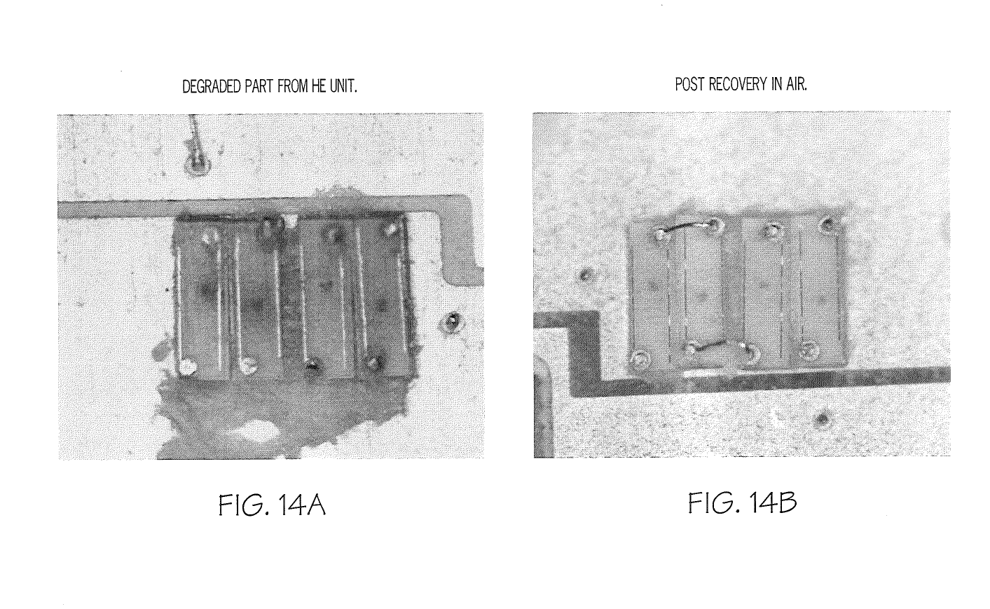

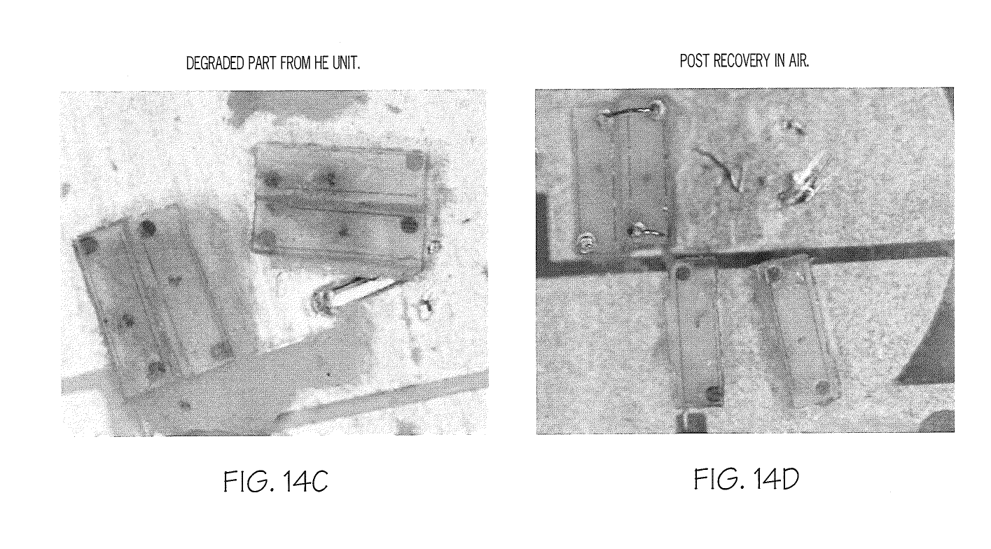

FIGS. 14A-14D illustrate various samples. Images in FIGS. 14A and 14C are from a first sapphire sample that was used to eliminate the flux variable. As shown in FIGS. 14A and 14C, significant degradation is shown, with visible browning seen in the attachment glue. Browning on the LED surface was less clear, and the white solder mask was not discolored. FIGS. 14B and 14D show a second set of devices to look at reversibility. As shown, these devices recover to within about 10% of their starting LF in air. Recovery was slower. Moreover, no visible browning was seen in the post-recovery, with the exception of the center dot seen on all parts, which appears to be related to the dot dispense of the silicone.

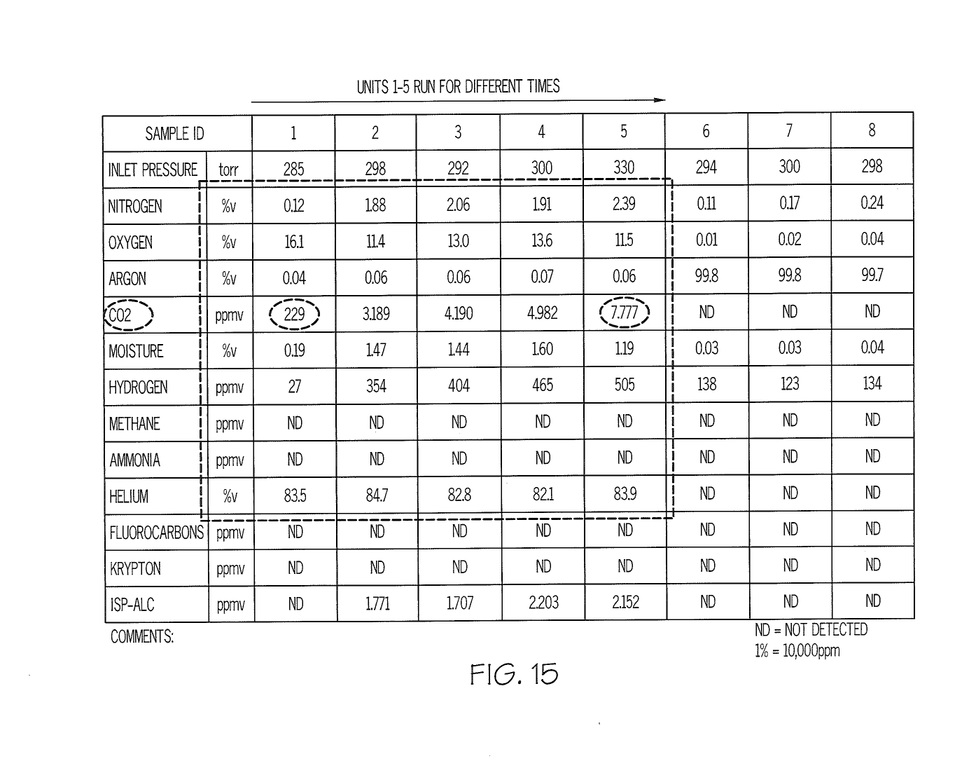

FIG. 15 is a table of unit gas analysis for units run for different lengths of time in a targeted 90/10 helium/atmosphere. As shown in FIG. 15, these results show increasing levels of Co₂/Co/H₂O, etc. These are all consistent with the byproducts of the breakdown and oxidation of organic compounds.

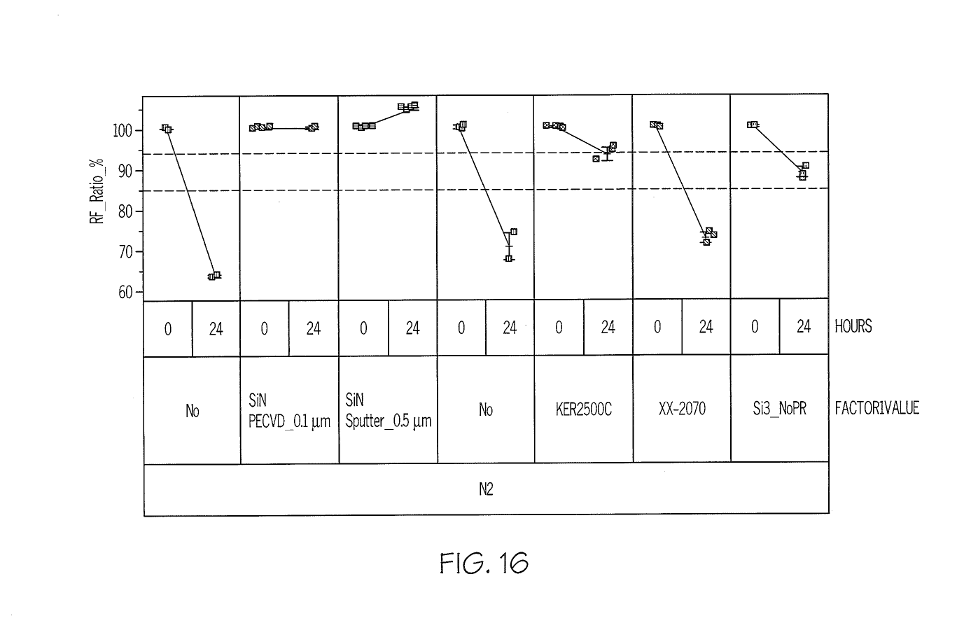

FIG. 16 graphically illustrates results for other thicknesses of silicon nitride and other materials. Specifically, the first column of FIG. 16 illustrates substantial degradation in an untreated light emitting surface over a 24 hour period. In contrast, the second column shows very little degradation for a silicon nitride layer that is about 0.1 μm thick and that is fabricated using PECVD. Accordingly, even thinner silicon nitride layers than were described above may be used. The third column also shows no degradation over a 24 hour period with a sputtered layer of silicon nitride that is about 0.5 μm thick. The remaining columns of FIG. 16 show different silicones and another polymer coating for comparison to the silicon nitride layer.

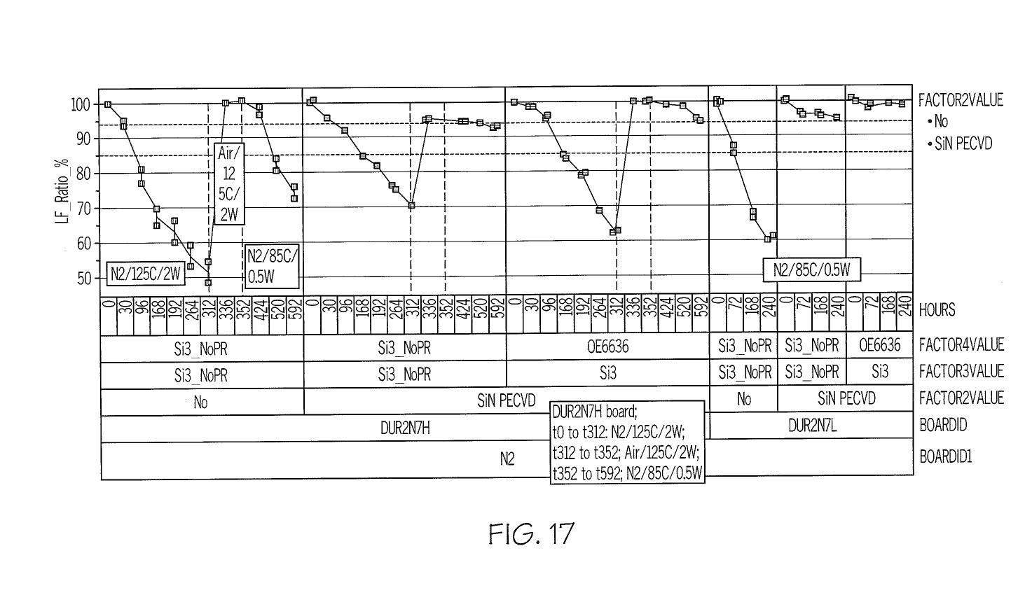

FIG. 17 illustrates a temperature dependence on the effects of degradation of the light emitting surface. Specifically, although FIG. 17 suggests that role of the phosphor layer itself cannot yet be completely ruled out as having some catalytic activity, the data of FIG. 17 suggests that increased temperature is a factor in the degradation difference when a phosphor layer is present. Referring to FIG. 17, without the silicon nitride layer, the degradation rate is similar for devices that are run at about 125° C. and about 2 W input and those that are run at about 85° C. and about 0.5 W input. In contrast, with the silicon nitride layer present, the degradation is significantly lower at the 85° C./0.5 W condition.

The results of FIG. 17 suggest that the light emitting surface reaction dominates, but once it is taken out of the equation by the silicon nitride coating, the temperature becomes a factor. However, since photocatalytic activity might increase as a function of temperature, the data of FIG. 17 is not able to quantify the contribution of the surface reaction compared to the temperature. It is also possible that at the 125° C./2 W condition, a photothermal breakdown of the VOCs is present. Literature on the topic would not suggest that these energy levels are high enough, given the wavelength and temperature, but flux density may be high enough to provide photothermal breakdown of the VOCs. Preliminary tests on devices that run about 90° C., rather than at about 125° C., have found that at about 140 hours, there is no significant degradation, regardless of the atmosphere. Accordingly, a photothermal breakdown of the VOCs may be taking place at the higher temperature.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

1. A light emitting device comprising:
a Light Emitting Diode (LED) that includes a light emitting surface;
a silicon nitride layer on the light emitting surface; and
a sealed environment surrounding the light emitting surface.

2. A light emitting device according to claim 1 wherein the silicon nitride layer is directly on and covers the light emitting surface.

3. A light emitting device according to claim 2:
wherein the LED comprises a diode region and a substrate, wherein the light emitting surface comprises an outer surface of the substrate that is free of an opaque region thereon, including a substrate face remote from the diode region and at least one substrate sidewall between the diode region and the substrate face; and
wherein the silicon nitride layer is directly on and covers the substrate face and the at least one substrate sidewall.

4. A light emitting device according to claim 3:
wherein the light emitting surface further comprises at least one diode region sidewall; and
wherein the silicon nitride layer is further directly on and covers the at least one diode region sidewall.

5. A light emitting device according to claim 4:
wherein the light emitting surface further comprises a diode region face that is remote from the substrate; and
wherein the silicon nitride layer is further directly on and covers the diode region face.

6. A light emitting device according to claim 2:
wherein the LED comprises a diode region and a substrate, wherein the light emitting surface comprises an outer surface of the diode region that is free of an opaque region thereon, including a diode region face remote from the substrate and at least one diode region sidewall between the substrate and the diode region face; and
wherein the silicon nitride layer is directly on and covers the diode region face and the at least one diode region sidewall.

7. A light emitting device according to claim 3 wherein the diode region comprises Group-III nitride-based semiconductor layers and the substrate comprises silicon carbide or sapphire.

8. A light emitting device according to claim 6 wherein the diode region comprises Group-III nitride-based semiconductor layers and the substrate comprises silicon,

9. A light emitting device according to claim 1 further comprising a phosphor layer on the silicon nitride layer, remote from the light emitting surface.

10. A light emitting device according to claim 1 wherein the sealed environment comprises a sealed gaseous environment.

11. A light emitting device according to claim 10 wherein the sealed gaseous environment consists essentially of helium.

12. A light emitting device according to claim 10 wherein the sealed gaseous environment comprises less oxygen than air and/or more helium than air.

13. A light emitting device comprising:
a Light Emitting Diode (LED) that includes a light emitting surface;
a silicon nitride layer directly on and completely covering the light emitting surface; and
a sealed environment surrounding the light emitting surface.

14. A light emitting device according to claim 13:
wherein the LED comprises a diode region and a substrate, wherein the light emitting surface comprises an outer surface of the substrate that is free of an opaque region thereon, including a substrate face remote from the diode region and at least one substrate sidewall between the diode region and the substrate face; and
wherein the silicon nitride layer is directly on and completely covers the substrate face and the at least one substrate sidewall.

15. A light emitting device according to claim 14:
wherein the light emitting surface further comprises at least one diode region sidewall; and
wherein the silicon nitride layer is further directly on and completely covers the at least one diode region sidewall.

16. A light emitting device according to claim 15:
wherein the light emitting surface further comprises a diode region face that is remote from the substrate; and
wherein the silicon nitride layer is further directly on and completely covers the diode region face.

17. A light emitting device according to claim 13:
wherein the LED comprises a diode region and a substrate, wherein the light emitting surface comprises an outer surface of the diode region that is free of an opaque region thereon, including a diode region face remote from the substrate and at least one diode region sidewall between the substrate and the diode region face; and
wherein the silicon nitride layer is directly on and completely covers the diode region face and the at least one diode region sidewall.

18. (canceled)

19. A light emitting device according to claim 13 wherein the sealed environment comprises a sealed gaseous environment.

20. A light emitting device according to claim 19 wherein the sealed gaseous environment consists essentially of helium.

21. A light emitting device according to claim 19 wherein the sealed gaseous environment comprises less oxygen than air and/or more helium than air.

22. A light emitting device comprising:
a Light Emitting Diode (LED) that includes a light emitting surface;
a substance blocking layer directly on and completely covering the light emitting surface; and
a sealed environment surrounding the light emitting surface.

23. A light emitting device according to claim 22:
wherein the LED comprises a diode region and a substrate, wherein the light emitting surface comprises an outer surface of the substrate that is free of an opaque region thereon, including a substrate face remote from the diode region and at least one substrate sidewall between the diode region and the substrate face; and
wherein the substance blocking layer is directly on and completely covers the substrate face and the at least one substrate sidewall.

24. A light emitting device according to claim 23:
wherein the light emitting surface further comprises at least one diode region sidewall; and
wherein the substance blocking layer is further directly on and completely covers the at least one diode region sidewall.

25. A light emitting device according to claim 24:
wherein the light emitting surface further comprises a diode region face that is remote from the substrate; and
wherein the substance blocking layer is further directly on and completely covers the diode region face.

26. A light emitting device according to claim 22:
wherein the LED comprises a diode region and a substrate, wherein the light emitting surface comprises an outer surface of the diode region that is free of an opaque region thereon, including a diode region face remote from the substrate and at least one diode region sidewall between the substrate and the diode region face; and
wherein the substance blocking layer is directly on and completely covers the diode region face and the at least one diode region sidewall.

27. A light emitting device according to claim 22 wherein the substance blocking layer comprises a carbon blocking layer, a volatile organic compound blocking layer and/or a moisture blocking layer.

28. A light emitting diode according to claim 22 wherein the substance blocking layer comprises a plurality of sublayers.

29. A light emitting diode according to claim 22 wherein the substance blocking layer comprises silicon nitride.

30. A light emitting diode according to claim 22 wherein the substance blocking layer comprises boron nitride.

31. A light emitting device according to claim 22 wherein the sealed environment comprises a sealed gaseous environment.

32. A light emitting device according to claim 31 wherein the sealed gaseous environment consists essentially of helium.

33. A light emitting device according to claim 31 wherein the sealed gaseous environment comprises less oxygen than air and/or more helium than air.

34.-35. (canceled)
